(19) United States
(12) Patent Application Publication
(10) Pub. No.: US 2005/0136340 A1
(43) Pub. Date: Jun. 23, 2005

(54) Lithographic apparatus and methods, patterning structure and method for making a patterning structure, device manufacturing method, and device manufactured thereby

(75) Inventors: Johannes Jacobus Matheus Baselmans, Oirschot (NL); Hugo Augustinus Joseph Cramer, Eindhoven (NL); Adtianus Franciscus Petrus Engelen, Waalre (NL); Jozef Maria Finders, Veldhoven (NL); Carsten Andreas Kohler, Veldhoven (NL); Shih-En Tseng, Hsin-Tien (TW)

Correspondence Address: PILLSBURY WINTHROP SHAW PITTMAN, LLP, P.O. BOX 10500, MCLEAN, VA, 22102, US

(73) Assignee: ASML NETHERLANDS B.V., Veldhoven (NL)

(21) Appl. No.: 10/972,783

(22) Filed: Oct. 26, 2004

Related U.S. Application Data
(63) Continuation-in-part of application No. 10/109,038, filed on Mar. 29, 2002, now Pat. No. 6,809,797.
(63) Continuation-in-part of application No. 09/905,198, filed on Jul. 16, 2001, now Pat. No. 6,887,625.
(60) Provisional application No. 60/244,657, filed on Nov. 1, 2000.

(30) Foreign Application Priority Data
Mar. 30, 2001 (EP) 01303036.6
Jul. 21, 2000 (EP) 00306237.9

(51) Int. Cl. G06F 17/50; G03F 9/00; G03C 5/00

(52) U.S. Cl. 430/5; 716/21; 430/394

(57) ABSTRACT

Without changing the initial illumination setting and resist process condition, a method according to one embodiment includes manipulating the design shape by application of additional and non-printable assist features (“sub-resolution assist features” or “SRAF”), such that CD sensitivities of the pattern feature are minimized. The SRAF may comprise chrome dots, or any other design objects of different sizes, shapes, and/or types, which can modulate the intensity and/or phase of the original pattern. to minimize an aberration sensitivity of selected ones of the plurality of pattern features A pattern that was not designed to include SRAF may be modified to include SRAF. In such a method, one or more aspects of the assist features are selected to reduce the aberration-induced image variation for a pattern and its sensitivity to aberrations.

### RELATED APPLICATIONS

This application is a continuation-in-part of and claims benefit of U.S. patent application Ser. No. 10/109,038, filed Mar. 29, 2002, which application is hereby incorporated by reference and which claims priority from European Patent Application No. EP 01303036.6, filed Mar. 30, 2001. This application is also a continuation-in-part of and claims benefit of U.S. patent application Ser. No. 09/905,198, filed Jul. 16, 2001, which application is hereby incorporated by reference and which claims priority from U.S. Provisional Patent Application No. 60/244,657, filed Nov. 1, 2000, and European Patent Application No. EP 00306237.9, filed Jul. 21, 2000.

### FIELD

The invention relates to lithographic apparatus and methods.

### BACKGROUND

In general, a lithographic projection apparatus comprises a radiation system to supply a projection beam of radiation, a support structure for supporting patterning structure, the patterning structure to pattern the projection beam according to a desired pattern, a substrate table for holding a substrate, and a projection system for projecting the patterned beam onto a target portion of the substrate.

The term “patterning structure” as here employed should be broadly interpreted as referring to structure or means that can be used to endow an incoming radiation beam with a patterned cross-section, corresponding to a pattern that is to be created in a target portion of the substrate; the term “light valve” can also be used in this context. Generally, the said pattern will correspond to a particular functional layer in a device being created in the target portion, such as an integrated circuit or other device (see below). Examples of such patterning structure include:

A mask. The concept of a mask is well known in lithography, and it includes mask types such as binary, alternating phase-shift, and attenuated phase-shift, as well as various hybrid mask types. Placement of such a mask in the radiation beam causes selective transmission (in the case of a transmissive mask) or reflection (in the case of a reflective mask) of the radiation impinging on the mask, according to the pattern on the mask. In the case of a mask, the support structure will generally be a mask table, which ensures that the mask can be held at a desired position in the incoming radiation beam, and that it can be moved relative to the beam if so desired.

A programmable mirror array. One example of such a device is a matrix-addressable surface having a viscoelastic control layer and a reflective surface. The basic principle behind such an apparatus is that (for example) addressed areas of the reflective surface reflect incident light as diffracted light, whereas unaddressed areas reflect incident light as undiffracted light. Using an appropriate filter, the said undiffracted light can be filtered out of the reflected beam, leaving only the diffracted light behind; in this manner, the beam becomes patterned according to the addressing pattern of the matrix-adressable surface. An alternative embodiment of a programmable mirror array employs a matrix arrangement of tiny mirrors, each of which can be individually tilted about an axis by applying a suitable localized electric field, or by employing piezoelectric actuation means. Once again, the mirrors are matrix-addressable, such that addressed mirrors will reflect an incoming radiation beam in a different direction to unaddressed mirrors; in this manner, the reflected beam is patterned according to the addressing pattern of the matrix-addressable mirrors. The required matrix addressing can be performed using suitable electronic means. In both of the situations described hereabove, the patterning structure can comprise one or more programmable mirror arrays. More information on mirror arrays as here referred to can be gleaned, for example, from U.S. Pat. No. 5,296,891 and U.S. Pat. No. 5,523,193, and PCT patent applications WO 98/38597 and WO 98/33096, which are incorporated herein by reference. In the case of a programmable mirror array, the said support structure may be embodied as a frame or table, for example, which may be fixed or movable as required.

A programmable LCD array. An example of such a construction is given in U.S. Pat. No. 5,229,872, which is incorporated herein by reference. As above, the support structure in this case may be embodied as a frame or table, for example, which may be fixed or movable as required.

For purposes of simplicity, the rest of this text may, at certain locations, specifically direct itself to examples involving a mask and mask table; however, the general principles discussed in such instances should be seen in the broader context of the patterning structure as hereabove set forth.

Lithographic projection apparatus can be used, for example, in the manufacture of integrated circuits (ICs). In such a case, the patterning structure may generate a circuit pattern corresponding to an individual layer of the IC, and this pattern can be imaged onto a target portion (e.g. comprising one or more dies) on a substrate (silicon wafer) that has been coated with a layer of radiation-sensitive material (resist). In general, a single wafer will contain a whole network of adjacent target portions that are successively irradiated via the projection system, one at a time. In current apparatus employing patterning by a mask on a mask table, a distinction can be made between two different types of machine. In one type of lithographic projection apparatus, each target portion is irradiated by exposing the entire mask pattern onto the target portion at one time; such an apparatus is commonly referred to as a wafer stepper. In an alternative apparatus—commonly referred to as a step-and-scan apparatus—each target portion is irradiated by progressively scanning the mask pattern under the projection beam in a given reference direction (the “scanning” direction) while synchronously scanning the substrate table parallel or anti-parallel to this direction; since, in general, the projection system will have a magnification factor M (generally <1), the speed V at which the substrate table is scanned will be a factor M times that at which the mask table is scanned. More information with regard to lithographic devices as here described can be gleaned, for example, from U.S. Pat. No. 6,046,792, incorporated herein by reference.

In a typical manufacturing process using a lithographic projection apparatus, a pattern (e.g. in a mask) is imaged onto a substrate that is at least partially covered by a layer of radiation-sensitive material (resist). Prior to this imaging step, the substrate may undergo various procedures, such as priming, resist coating and a soft bake. After exposure, the substrate may be subjected to other procedures, such as a post-exposure bake (PEB), development, a hard bake and measurement/inspection of the imaged features. This array of procedures is used as a basis to pattern an individual layer of a device, e.g. an IC. Such a patterned layer may then undergo various processes such as etching, ion-implantation (doping), metallization, oxidation, chemo-mechanical polishing, etc., all intended to finish off an individual layer. If several layers are required, then the whole procedure, or a variant thereof, will have to be repeated for each new layer. Eventually, an array of devices will be present on the substrate (wafer). These devices are then separated from one another by a technique such as dicing or sawing, whence the individual devices can be mounted on a carrier, connected to pins, etc. Further information regarding such processes can be obtained, for example, from the book “Microchip Fabrication: A Practical Guide to Semiconductor Processing”, Third Edition, by Peter van Zant, McGraw-Hill Publishing Co., 1997, ISBN 0-07-067250-4.

For the sake of simplicity, the projection system may hereinafter be referred to as the “lens”; however, this term should be broadly interpreted as encompassing various types of projection system, including refractive optics, reflective optics, catadioptric systems, and charged particle optics, for example. The radiation system may also include an illumination system having components operating according to any of these design types for directing, shaping or controlling the projection beam of radiation, and such components may also be referred to below, collectively or singularly, as a “lens”. Further, the lithographic apparatus may be of a type having two or more substrate tables (and/or two or more mask tables). In such “multiple stage” devices the additional tables may be used in parallel, or preparatory steps may be carried out on one or more tables while one or more other tables are being used for exposures. Dual stage lithographic apparatus are described, for example, in U.S. Pat. No. 5,969,441 and PCT International Application No. WO 98/40791, incorporated herein by reference.

When performing imaging in a lithographic projection apparatus, despite the great care with which the projection system is designed and the very high accuracy with which the system is manufactured and controlled during operation, the image can still be subject to aberrations such as, for example, distortion (i.e. a non-uniform image displacement in the target portion at the image plane: the XY-plane), lateral image shift (i.e. a uniform image displacement in the target portion at the image plane), image rotation, asymmetric magnification, and focal plane deformation (i.e. a non-uniform image displacement in the Z-direction, for instance due to field curvature). Notice that, in general, image errors are not necessarily uniform, and can vary as a function of position in the image field. Distortion and focal plane deformation can lead to overlay and focus errors, for example overlay errors between different mask structures, and line-width errors. As the size of features to be imaged decreases, these errors can become intolerable.

Consequently, it is desirable to provide compensation (such as adjustment of the projection system and/or substrate) to correct for, or at least attempt to minimize, these errors. This presents the problems of first measuring the errors and then calculating appropriate compensation. Previously, alignment systems were used to measure the displacements in the image field of alignment marks. However, alignment marks typically consist of relatively large features (of the order of a few microns), causing them to be very sensitive to aberrations of the projection system. The alignment marks are unrepresentative of the actual features being imaged, and because the imaging errors depend inter alia on feature size, the displacements measured and compensations calculated did not necessarily optimize the image for the desired features.

Another problem occurs when, for instance because of residual manufacturing errors, the projection system features an asymmetric variation of aberration over the field. These variations may be such that at the edge of the field the aberration becomes intolerable.

A further problem may occur when using phase-shift masks (PSMs). Conventionally, the phase shift in such masks should be precisely 180 degrees. The control of the phase is critical; deviation from 180 degrees is detrimental. PSMs, which are expensive to make, must be carefully inspected, and any masks with substantial deviation in phase shift from 180 degrees will generally be rejected. This leads to increased mask prices.

A further problem may arise with the increasing requirements imposed on the control of critical dimension (“CD”). The critical dimension is the smallest width of a line or the smallest space between two lines permitted in the fabrication of a device. In particular the control of the uniformity of CD, the so-called “CD uniformity”, is of importance. In lithography, efforts to achieve better line width control and CD uniformity have recently led to the definition and study of particular error types occurring in features, as obtained upon exposure and processing operations as described above. For instance, such image error types are an asymmetric distribution of CD over a target portion, an asymmetry of CD with respect to defocus (which results in a tilt of Bossung curves), asymmetries of CD within a feature comprising a plurality of bars (commonly referred to as Left-Right asymmetry), asymmetries of CD within a feature comprising either two or five bars (commonly known as L1-L2 and L1-L5, respectively), differences of CD between patterns that are substantially directed along two mutually orthogonal directions (for instance the so-called “H-V” lithographic error), and for instance a variation of CD within a feature, along a bar, commonly known as “C-D”. Just as the aberrations mentioned above, these errors are generally non-uniform over the field. For simplicity we will hereafter refer to any of these error types—including the errors such as, for example, distortion, lateral image shift, image rotation, asymmetric magnification, and focal plane deformation—as “lithographic errors”, i.e. feature-deficiencies of relevance for the lithographer.

Lithographic errors may be caused by specific properties of the lithographic projection apparatus. For instance, the aberration of the projection system, or imperfections of the patterning structure and imperfections of patterns generated by the patterning structure, or imperfections of the projection beam may cause lithographic errors. However, also nominal properties (i.e. properties as designed) of the lithographic projection apparatus may cause unwanted lithographic errors. For instance, residual lens aberrations which are part of the nominal design may cause lithographic errors. For reference hereafter, we will refer to any such properties that may cause lithographic errors as “properties.”

As mentioned above, the image of a pattern can be subject to aberrations of the projection system. A resulting variation of CD (for example, within a target portion) can be measured and subsequently be mapped to an effective aberration condition of the projection system which could produce said measured CD variation. A compensation can then be provided to the lithographic projection system such as to improve CD uniformity. Such a CD-control method may comprise imaging a plurality of test patterns at each field point of a plurality of field points, a subsequent processing of the exposed substrate, and a subsequent CD measurement for each of the imaged and processed test patterns. Consequently, this method tends to be time consuming and not suitable for in-situ CD control. With increasing demands on throughput (i.e. the number of substrates that can be processed in a unit of time) as well as CD uniformity, the control, compensation and balancing of lithographic errors must be improved, and hence, there is the problem of furthering appropriate control of properties.

Separately, it is known to provide so-called “assist features” in masks to improve the image projected onto the resist and ultimately the developed device. Assist features are features that are not intended to appear in the pattern developed in the resist, but are provided in the mask to take advantage of diffraction effects so that the developed image more closely resembles the desired circuit pattern. Assist features are generally “sub-resolution,” meaning that they are smaller in at least one dimension than the smallest feature in the mask that will actually be resolved on the wafer. Assist features may have dimensions defined as fractions of the “critical dimension,” which is the smallest width of a feature or smallest separation between features in the mask and is often the resolution limit of the lithographic projection apparatus with which the mask is to be used. Note though that because the mask pattern is generally projected with a magnification of less than 1, e.g. ¼ or ⅕, the assist feature on the mask may have a physical dimension larger than the smallest feature on the wafer.

Two types of assist features are currently known. Scattering bars are lines with a sub-resolution width placed on one or both sides of an isolated conductor to mimic proximity effects that occur in densely packed regions of a pattern. Serifs are additional areas of various shapes placed at the corners and ends of conductor lines, or the corners of rectangular features, to make the end of the line, or the corner, more nearly square or round, as desired (note in this context that assist features commonly referred to as “hammerheads” are regarded as being a form of serif). Further information on the use of scattering bars and serifs can be found in U.S. Pat. No. 5,242,770 and U.S. Pat. No. 5,707,765, for example, which are incorporated herein by reference.

Contact holes, or vias, in integrated circuits may cause particular problems in imaging. Because the contact holes often have to be formed through numerous or relatively thick process layers previously formed on the wafer, typically they must be patterned into a relatively thick layer of photoresist, requiring an increased depth of focus in the aerial image of the mask pattern.

### SUMMARY

A device manufacturing method according to an embodiment of the invention comprises selecting an exposure condition, the exposure condition including at least one of the group consisting of an illumination condition and a resist process condition; determining a sensitivity of a pattern to a nonideality of a lithographic apparatus, wherein the sensitivity is based on the selected exposure condition; adding a plurality of non-printing assist features to the pattern to obtain a modified pattern, including selecting at least one of the group consisting of a type, a size, and a location of each of the plurality of non-printing assist features to reduce the sensitivity; and projecting a beam of radiation patterned according to the modified pattern.

A method of making a mask according to another embodiment comprises defining a plurality of pattern features that contrast with a background and represent features to be printed in manufacture of a device, each of the pattern features being configured to at least partially enclose an area; and defining a plurality of non-printing assist features that contrast with the background and are smaller than the pattern features, wherein said defining a plurality of assist features comprises selecting at least one of the group consisting of a type, a size, and a location of each of the plurality of non-printing assist features to reduce a sensitivity of the pattern to a system nonideality.

A mask according to a further embodiment comprises a plurality of pattern features that contrast with a background and represent features to be printed in manufacture of a device, each of the pattern features being configured to at least partially enclose an area; and a plurality of non-printing assist features that contrast with the background and are smaller than said pattern features, wherein said plurality of assist features is arranged to reduce a sensitivity of the pattern to a system nonideality under a predetermined illumination condition.

A pattern that was not necessarily designed to include non-printing assist features may be modified to include the non-printing assist features. Assist features may be applied to largely reduce sensitivities to higher order aberrations, while the sensitivities to lower order may be increased slightly. Fortunately modern scanners are provided with some control knobs on lower order aberrations. So based on the aberration sensitivities of, e.g., the obtained “U”-shaped pattern with SR AF, the aberration control knobs of the exposure tool can be used to compensate the contribution of the largely uncorrectable aberrations to CDU. Thus, printing of a pattern may be improved by applying non-printing assist features to the pattern and/or adjusting lower order aberrations without changing the illumination condition and without modifying other device patterns.

Furthermore, methods are provided for manipulating the design shape with the application of SRAF to minimize the aberration sensitivity of a pattern feature without changing the original tool setting and resist process condition. Moreover, the combination with the “customized aberration setup” using the obtained customer pattern with SRAF can further improve the CDU performance with available aberration manipulators of the exposure tools.

### BRIEF DESCRIPTION OF THE DRAWINGS

Embodiments of the invention will now be described, by way of example only, with reference to the accompanying schematic drawings in which:

FIG. 1 depicts a lithographic projection apparatus according to an embodiment of the invention; and

FIG. 2 depicts the imaging of a decentered pattern, where the decenter is the compensator for alleviating the effects of a lithographic error. The graph at the bottom shows the boundary of the area of x, y field points contributing to the merit function, in relation to the boundary of the full field target portion. The horizontal axis represents the x-position along the slit, the vertical axis represents the y-position (a position along the scanning direction). The graph in the middle shows a plot of a lithographic error, which is asymmetrically distributed along the x-axis. The horizontal axis represents the x-position along the slit, the vertical axis represents the magnitude of a lithographic error.

FIG. 3 depicts a part of a mask pattern for printing contact holes in the manufacture of a dynamic random access memory (DRAM);

FIG. 4 depicts a part of a mask pattern according to a first embodiment of the present invention for printing contact holes in a DRAM;

FIG. 5 is a graph of intensities of part of the aerial images produced by the mask patterns of FIGS. 3 and 4;

FIG. 6 depicts a part of an alternative mask pattern for printing contact holes;

FIG. 7 depicts a part of a mask pattern according to a second embodiment of the invention;

FIG. 8 is a graph of intensities of part of the aerial images produced by the mask patterns of FIGS. 6 and 7;

FIG. 9 depicts part of a mask pattern for printing rectangular features;

FIG. 10 depicts part of a mask pattern according to a third embodiment of the invention for printing rectangular features;

FIG. 11 is a contour plot of intensities of a part of the aerial images produced by the mask patterns of FIGS. 9 and 10; and

FIG. 12 depicts part of a mask pattern according to a fourth embodiment of the invention.

FIG. 13 shows a plurality of “U”-shaped pattern features.

FIG. 14 shows an assist feature within a pattern feature.

FIG. 15 shows assist features applied at locations within similar neighboring pattern features.

FIG. 16 shows an N-bar structure with application of edge assist features.

FIG. 17 shows an effect of application of edge assist features to an N-bar structure.

FIG. 18 shows nonprintable center assist features applied between sets of N-bar structure.

FIGS. 19 and 20 show (L-R) sensitivity improvements to 1 wave and to 3 wave aberrations, respectively.

In the drawings, like references indicate like parts.

### DETAILED DESCRIPTION

Although specific reference may be made in this text to the use of apparatus and methods according to embodiments of the invention in the manufacture of ICs, it should be explicitly understood that such apparatus and methods have many other possible applications. For example, they may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as being replaced by the more general terms “mask”, “substrate” and “target portion”, respectively.

In the present document, the terms “radiation” and “beam” are used to encompass all types of electromagnetic radiation, including, but not limited to, ultraviolet radiation (e.g. with a wavelength of 365, 248, 193, 157 or 126 nm) and EUV (extreme ultra-violet radiation, e.g. having a wavelength in the range 5-20 nm); in principle, these terms also encompass X rays, electrons and ions. Also herein, embodiments of the invention are described using a reference system of orthogonal X, Y and Z directions, and rotation about an axis parallel to the I direction is denoted Ri. Further, unless the context otherwise requires, the term “vertical” (Z) used herein is intended to refer to the direction normal to the substrate or mask surface, or parallel to the optical axis of an optical system, rather than implying any particular orientation of the apparatus. Similarly, the term “horizontal” refers to a direction parallel to the substrate or mask surface, or perpendicular to the optical axis, and thus normal to the “vertical” direction.

Although preferably all lithographic errors shall be minimized, this will in general not be possible since there are not enough compensators available. Therefore, it is useful to define a merit function which suitably describes the quality of the imaging process in terms of a sum of weighted lithographic errors. A weight assigned to a lithographic error shall be indicative of the relative importance of that lithographic error. Compensation can be used to optimize (i.e. to minimize the value of) the merit function, such as to optimize the imaging and the resulting lithographic process.

As explained above, lithographic errors depend on properties (of the lithographic projection apparatus) and can be calculated using, for instance, commercially available lithography simulation software such as Prolith™, Solid-C™ or LithoCruiser™. For instance, given specific (e.g. critical) pattern features to be imaged, given specific pattern errors (such as phase errors with a phase shift mask), given the aberration of the projection system, given the data concerning the radiation sensitive layer on the substrate, and given a set of properties (e.g. properties of the radiation beam, such as radiation energy and/or wavelength), predictions regarding CD uniformity or feature-specific deficiencies can be made with these simulation programs. By introducing small variations of the properties (for instance, by introducing small variations of the projection lens aberration) and calculating the corresponding changes in the lithographic errors, coefficients quantifying the relationship between a lithographic error and said properties can be established.

Obtaining information on properties may comprise (in-situ) measuring of properties. For example, the actual aberration condition of the projection system can be measured in-situ using a suitable technique such as one of those disclosed in European Patent Application Number EP 1 128 217 A2 and in P. Venkataraman, et al., “Aberrations of steppers using Phase Shifting Point Diffraction Interferometry”, in Optical Microlithography XIII, J. Progler, Editor, Proceedings of SPIE Vol. 4000, 1245-1249 (2000). One potential advantage of a method according to an embodiment of the present invention is that such a method does not necessarily comprise the operation of processing an exposed substrate.

Key to the control of lithographic errors is the ability to compensate, or at least affect, these lithographic errors. Any structure and/or device enabling such control will be referred to hereafter as a compensator. By the term “compensation” mentioned above, any change of a property caused by activating or otherwise applying a compensator is meant, and the term compensation as used herein will include this meaning. Compensators suitable for use with a lithographic projection apparatus include, for instance, structures enabling a fine positioning (an X-, Y-, and Z-translation, and a rotation about the X-, Y-, and Z-axis) of the holder for holding the patterning structure, structures enabling a similar fine positioning of the substrate table, devices to move or deform optical elements (in particular, to finely position, using an X-, Y-, and Z-translation/rotation, optical elements of the projection system), and, for instance, structures to change the energy of the radiation impinging on the target portion. However, suitable compensators are not limited to said examples: for instance, structures or devices to change the wavelength of the radiation beam, to change the pattern, to change the index of refraction of gas-filled spaces traversed by the projection beam, and/or to change the spatial distribution of the intensity of the radiation beam may also serve to affect lithographic errors.

The optimization calculation is based on varying the available compensations. The calculation comprises minimization of the merit function. Since the merit function is available as a mathematical expression (relating lithographic errors to compensations), standard minimization routines such as a “weighted least squares optimization” can be used to find a set of compensations at which the merit function has a minimum.

By performing the optimization calculation, the quality of the imaging can be objectively improved, as defined by the merit function. The compensation enables, for example, one component of aberration of the projection system to be increased in order to decrease the effect of another aberration component, such that, on balance, the image quality as a whole is improved. In other words, preferably the improvement in one aspect of the imaging more than compensates for a change of a different aspect of the imaging. According to another example, the patterning structure can be translated, rotated and/or tilted (a form of rotation) in order to minimize the overall local displacement of the image from its ideal position across the whole image field. In a further example, linear comatic aberration can be introduced within the projection system to reduce or eliminate left-right asymmetry caused by 3-wave aberration. In a further example, spherical aberration can be introduced to compensate for “Bossung tilt” caused by a phase shift error in a phase shift mask, which would otherwise have to be rejected. Bossung tilt is the lithographic error whereby at best focus position there is a gradient in the graph of exposed feature width against focus position (said graph being a so-called Bossung curve).

Said properties (of, for example, the projection system) can be stored in a database for use in optimization calculations for exposures using the apparatus containing that projection system. The coefficients which quantify the relationship between those properties and a lithographic effect can also be stored in a database as sets or families of coefficients depending on pattern feature type, size, orientation, illumination mode, numerical aperture and so on.

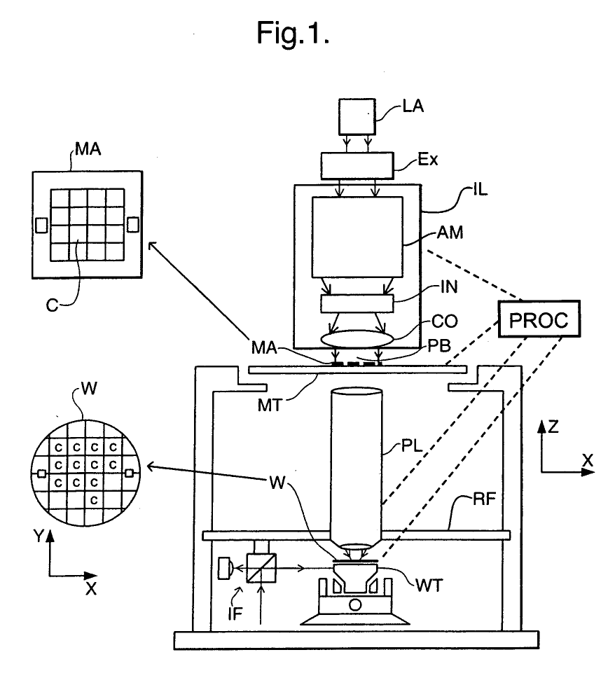

FIG. 1 schematically depicts a lithographic projection apparatus according to at least one embodiment of the invention. The apparatus comprises:
a radiation system Ex, IL, for supplying a projection beam PB of radiation (e.g. UV radiation such as for example generated by an excimer laser operating at a wavelength of 248 nm, 193 nm or 157 nm, or by a laser-fired plasma source operating at 13,6 nm). In this particular case, the radiation system also comprises a radiation source LA;
a first object table (mask table) MT provided with a mask holder for holding a mask MA (e.g. a reticle), and connected to a first positioning device for accurately positioning the mask with respect to item PL;
a second object table (substrate table) WT provided with a substrate holder for holding a substrate W (e.g. a resist-coated silicon wafer), and connected to a second positioning device for accurately positioning the substrate with respect to item PL;
a projection system (“lens”) PL (e.g. a quartz and/or CaF₂ lens system or a catadioptric system comprising lens elements made from such materials, or a mirror system) for imaging an irradiated portion of the mask MA onto a target portion C (e.g. comprising one or more dies) of the substrate W.

As here depicted, the apparatus is of a transmissive type (i.e. has a transmissive mask). However, in general, it may also be of a reflective type, for example (with a reflective mask). Alternatively, the apparatus may employ another kind of patterning structure, such as a programmable mirror array of a type as referred to above.

The source LA (e.g. a UV excimer laser, a laser-fired plasma source, a discharge source, or an undulator or wiggler provided around the path of an electron beam in a storage ring or synchrotron) produces a beam of radiation. This beam is fed into an illumination system (illuminator) IL, either directly or after having traversed a conditioner, such as a beam expander Ex, for example. The illuminator IL may comprise an adjuster AM for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam PB impinging on the mask MA has a desired uniformity and intensity distribution in its cross-section.

It should be noted with regard to FIG. 1 that the source LA may be within the housing of the lithographic projection apparatus (as is often the case when the source LA is a mercury lamp, for example), but that it may also be remote from the lithographic projection apparatus, the radiation beam which it produces being led into the apparatus (e.g. with the aid of suitable directing mirrors); this latter scenario is often the case when the source LA is an excimer laser. The present invention encompasses at least both of these scenarios.

The beam PB subsequently intercepts the mask MA, which is held on a mask table MT. Having traversed the mask MA, the beam PB passes through the lens PL, which focuses the beam PB onto a target portion C of the substrate W. With the aid of the second positioning device (and interferometric measuring means IF), the substrate table WT can be moved accurately, e.g. so as to position different target portions C in the path of the beam PB. Similarly, the first positioning device can be used to accurately position the mask MA with respect to the path of the beam PB, e.g. after mechanical retrieval of the mask MA from a mask library, or during a scan. In general, movement of the object tables MT, WT will be realized with the aid of a long-stroke module (coarse positioning) and a short-stroke module (fine positioning), which are not explicitly depicted in FIG. 1. However, in the case of a wafer stepper (as opposed to a step-and-scan apparatus) the mask table MT may just be connected to a short stroke actuator, or may be fixed.

Various implementations of the depicted apparatus can be used in at least two different modes:
1. In step mode, the mask table MT is kept essentially stationary, and an entire mask image is projected at one time (i.e. a single “flash”) onto a target portion C. The substrate table WT is then shifted in the x and/or y directions so that a different target portion C can be irradiated by the beam PB;
2. In scan mode, essentially the same scenario applies, except that a given target portion C is not exposed in a single “flash”. Instead, the mask table MT is movable in a given direction (the so-called “scan direction”, e.g. the y direction) with a speed v, so that the projection beam PB is caused to scan over a mask image; concurrently, the substrate table WT is simultaneously moved in the same or opposite direction at a speed V=Mv, in which M is the magnification of the lens PL (typically, M=¼ or ⅕). In this manner, a relatively large target portion C can be exposed, without having to compromise on resolution.

Image distortion and/or focal plane deformation occurring in the projected image may depend on various factors, such as the lens aberration, illumination mode used [e.g. numerical aperture (NA), pupil filling (sigma setting)], and the type and size of the feature imaged. The lens aberration can be expressed in terms of the Zernike expansion, in which the aberrated wavefront is given by the sum of a plurality of Zernike polynomials (functions of position in the image field) each multiplied by a respective Zernike coefficient. The image X, Y and Z displacements can be modeled by the following linear expressions:

$$\begin{matrix}dX ( x , y ) = {\sum }_{j}^{} \frac{\partial X}{\partial Zj} \cdot Zj ( x , y ) & ( 1 ) \\ dY ( x , y ) = {\sum }_{j}^{} \frac{\partial Y}{\partial Zj} \cdot Zj ( x , y ) & ( 2 ) \\ dF ( x , y ) = {\sum }_{j}^{} \frac{\partial F}{\partial Zj} \cdot Zj ( x , y ) & ( 3 )\end{matrix}$$

where:
dX, dY, dF are the respective X, Y and Z displacements;
(x, y) is a specific field location;
j is an index for the jth Zernike aberration;
Zj is an aberration coefficient representative of the contribution of the jth Zernike polynomial to the wavefront aberration at field point (xy); and

$$\frac{\partial }{\partial {Z}_{j}}$$
is the partial derivative of the displacement with respect to the jth Zernike aberration.

Notice that dX, dY and dF are lithographic errors, and that the coefficients Zⱼ are properties (of the imaging system including an object and image plane).

A further refinement is to write the Z-displacement dF as two components dV and dH which are the optimal focus positions along the Z-axis for so-called vertical and horizontal lines, respectively; these are features extending along they and x axes, respectively. Using this, and a different notation, the above equations can be rewritten, for the 37 Zernike aberrations, as:
dX(x,y)=A1.Z1(x,y)+A2.Z2(x,y)+ . . . +A37.Z37(x,y) (4)
dY(x,y)=B1.Z1(x,y)+B2.Z2(x,y)+ . . . +B37.Z37(x,y) (5)
dH(x,y)=C1.Z1(x,y)+C2.Z2(x,y)+ . . . +C37.Z37(x,y) (6)
dV(x,y)=D1.Z1(x,y)+D2.Z2(x,y)+ . . . +D37.Z37(x,y) (7)
where the partial derivatives have been replaced by equivalent sensitivity coefficients Ai, Bi, Ci, Di which express inter alia the effects of illumination mode, NA, sigma and pattern feature size and type.

A method of reducing errors may include operations of lens characterization, sensitivity coefficient calculation/selection, and compensation as described herein. In one example of a lens characterization operation, the intrinsic aberration of the lens is measured using a suitable technique, such as one of those disclosed in European Patent Application EP 1 128 217 A2, to obtain the Zernike coefficients (or previously measured values can be used). The Zernike coefficients are then multiplied by their respective Zernike functions to obtain a “field map” of the Zernike aberrations (Zⱼ(x,y) in the above notation), which is stored. This information depends only on the lens and is independent of the illumination and features. Performance of a lens characterization operation may be satisfied by retrieving an existing characterization of the lens (e.g. in terms of Zernike coefficients and/or similar factors such as Seidel coefficients) from storage (e.g. a database).

In one example of an operation of sensitivity coefficient calculation/selection, the sensitivity coefficients Ai, Bi, Ci, Di are calculated (or selected from precalculated values) for the exposure of a specific pattern feature, at a particular illumination setting. Such calculation (or precalculation) may be performed using known computational techniques, such as image simulation software, for example the program known as Solid-C™ supplied by Sigma-C GmbH of Germany. Other suitable software packages, such as one known as Prolith™ or LithoCruiser™, may alternatively be used. These sensitivity coefficients do not depend on the field location, so they only need to be calculated once per feature and illumination setting combination, and may then be stored in a database (e.g. for reuse). The sensitivity coefficients may be calculated and/or selected based on factors such as printing feature type and/or size, illumination mode and/or setting, and resist process conditions.

In one example of a compensation operation, a property of the apparatus is adjusted by determining and applying an appropriate compensation. For example, the field distribution of the X, Y and Z-displacements may be calculated for the exposure of a specific pattern feature, at a particular illumination setting, by means of the models (for example, equations (4) to (7)) and using the field map from operation 1 and the sensitivity coefficients from operation 2. A calculation is performed to determine what compensation to provide to minimize the image displacements for the whole field. Such a calculation can be based on a merit function of the form

$$\begin{matrix}S = w1 {\sum }_{x , y}^{} {( dX ( x , y ) )}^{2} + w2 {\sum }_{x , y}^{} {( dY ( x , y ) )}^{2} + \\ w3 {\sum }_{x , y}^{} {( dH ( x , y ) )}^{2} + w4 {\sum }_{x , y}^{} {( dV ( x , y ) )}^{2}\end{matrix} \qquad ( 8 )$$

where wi (i=1,2,3,4) are weights, and the sum over an appropriately chosen grid of field coordinates x,y ensures an averaging of the lithographic error over a target portion. The weights can be chosen at the discretion of the lithographer. For dX, dY, dH and dV one can substitute expressions (4), (5), (6) and (7) respectively.

A simple compensator is, for instance, the Z-position of the substrate, commonly called “focus”. It is well known that a change of focus, by moving the substrate through a distance dZ, affects primarily the value of Z4, and in this particular case, the effect is independent of the x,y position in the field. So, in order to incorporate the effect of the compensation dZ on the merit function (through the effect that dZ has on dX, dY, dH and dV), one has to substitute Z4+F4(dZ,x,y) for Z4 in the expressions (4), (5), (6) and (7), as used in equation (8), where the function F4(dZ,x,y) is simply given by
F4(dZ,x,y)=a4·dZ (9)
a4 being a (field independent) constant of proportionality which follows from aberration theory.

Notice, however, that in practice the compensation dZ will, besides this primary impact on Z4, also affect, as a secondary error, other Zernike aberration coefficients. Generally, the effect of a compensation C comprises a primary error on a few Zernike coefficients and a secondary change of balance between the other Zernike aberration coefficients. So, the effect of a set of n compensations Ci, with i=1,2, . . . , n, on the merit function can be visualized by replacing Zj(x,y) in the expressions (4), (5), (6) and (7), as used in equation (8), by Zj(x,y,C1,C2, . . . , Ci, . . . , Cn), where

$$\begin{matrix}Zj ( x , y , C1 , C2 , … , Ci , … , Cn ) = Zj ( x , y ) + \\ {\sum }_{i = 1}^{n} Fj ( Ci , x , y ) .\end{matrix} \qquad ( 10 )$$

The functions Fj(Ci,x,y) are (to good approximation) linearly dependent on Ci and vanish for Ci=0. Therefore, to a good approximation one obtains:

$$Zj ( x , y , C1 , C2 , … , Ci , … , Cn ) \approx Zj ( x , y ) + {\sum }_{i = 1}^{n} CiUji ( x , y ) \qquad ( 11 )$$

The constants of proportionality Uji(x,y) are defined by

$$Uji ( x , y ) = \frac{\partial Fj ( Ci , x , y )}{\partial Ci} , \qquad ( 12 )$$

and follow from the theory of aberrations or can be calculated using optical design software, such as for instance CodeV™. Notice that, in general, the constants of proportionality are field dependent. In the example above, a4 represents a special case where the constant of proportionality is field independent.

In view of the above, the merit function S depends on the compensations C1, C2, . . . , Cn. Then, using a standard minimization procedure such as a weighted least square optimization (see for instance the publication “Numerical Recipes in C”, First Edition, by William H. Press, Brian P. Flannery, Saul A. Teukolsky, and William T. Vetterling, Cambridge University Press, 1988), values of the compensations can be found for which S is at a minimum value.

Next, the projection apparatus is adjusted to provide the calculated compensation. Examples of available compensations include translation of the mask table (to shift the x, y co-ordinates); lens adjustment (e.g. to change the magnification and/or field curvature, using internal lens-element manipulators and/or telecentricity adjustment); rotation of the mask (reticle); adjustment of the mask height (e.g. to compensate for 3^{rd} order distortion); adjustment of the mask tilt; and adjustment of leveling (e.g. to compensate for z-displacement and tilt).

For a particular pattern to be imaged, the illumination setting to be used is usually predetermined to optimize contrast. Similarly, although the pattern may have many feature types, in practice one feature type will typically be the most critical. At operation 2, the sensitivity coefficients can be calculated for the predetermined illumination setting and the most critical feature type. Alternatively, a family of sets of sensitivity coefficients can be derived for a range of feature types and illumination settings and stored in a database. In such case, for example, operation 2 might be reduced to simply looking up in the database of coefficient families the set of sensitivity coefficients for a pattern, according to e.g. most critical feature type and/or predetermined illumination setting. The sensitivity coefficients, derived either way, can then be stored as the default values for that particular pattern. If the model of equations (4) to (7) is used, there will only be 37×4 coefficient values associated with each pattern.

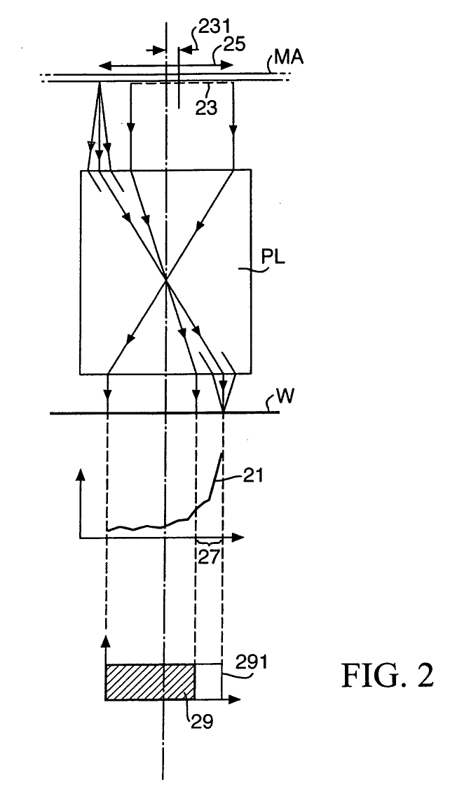

As described above, a translation of the mask table (holder for the patterning structure) is one of the compensators available. In one embodiment this translational degree of freedom is exploited to establish a decentered imaging of a pattern: see FIG. 2. A projection system PL of a scanning lithography apparatus is shown in FIG. 2 and is assumed to exhibit a strong asymmetric distribution 21 of, for instance, Z7(xy) along the x-direction. Such an asymmetry may be caused by residual manufacturing errors that occurred during the manufacturing of the projection system, and is known to be an important contributor to the lithographic error Left-Right asymmetry (LR asymmetry). If the pattern 23 that is to be imaged is smaller that the full field width 25, one can shift the pattern in the x-direction over a distance 231, such that the patterned beam traverses the projection system in a decentered manner. As a result, the portion 27 of the field which suffers strongly from Z7 is avoided, and the lithographic error LR asymmetry will be reduced. In this example, the merit function S will comprise a weighted term which accounts for LR asymmetry (with a weight w chosen by the lithographer):

$$S = … + w {\sum }_{x , y}^{} {( LRasymmetry ( x , y ) )}^{2} + … \qquad ( 13 )$$

The compensation 231 affects, in this embodiment, the relative position of the boundary 29 of the grid of x,y field points (that contribute to the merit function) with respect to the boundary 291 of the full field target portion.

As described above, a displacement-compensator may be used to minimize the X, Y and Z image displacements resulting from, for instance, aberration in the lens. Effectively the plane of the image and the wafer is shifted to balance aberration effects of the lens. Alternatively, or in addition, the aberration of the lens itself can be adjusted. For example, spherical aberration adjustment and comatic aberration adjustment can be provided (spherical and comatic aberration are the lowest order even and odd aberrations, respectively).

Aberration adjustment may influence the distribution of all aberrations (i.e. change the values of the Zernike coefficients), so such adjustment should be taken into account in the lens characterization operation. The means of adjusting the aberration may also influence the sensitivity coefficients Ai, Bi, Ci, Di, so should also be taken into account in the operation of sensitivity coefficient calculation/selection. Lens manipulation primarily influences the low-order Zernike aberrations (Z2, Z3, Z4, Z5). The impact of these aberrations on the imaging is displacement and defocus (astigmatism), and this impact is independent of the pattern feature structure and the illumination settings.

Often it is best simply to minimize the aberration of the lens. However, as can be seen from equations (4) to (7), the ability to adjust the aberrations Zj may give more adjustable parameters, and hence more degrees of freedom, for minimizing the displacement errors.

Error reduction need not be limited to reducing overlay and focus errors (minimizing the displacements). Compensation can be used to reduce any lithographic effect that is detrimental to image quality. For example, left-right asymmetry (LR asymmetry) caused by 3-wave aberration can be reduced by introducing linear comatic aberration within the system. In other words, increasing one aberration can be used to decrease another aberration such that, on balance, the quality as a whole of a printed feature is improved. It is then necessary to include LR asymmetry in the merit function. Let us denote an arbitrary lithographic error, that is to be minimized, by LEj, j=1,2,3,4, . . . For instance, we may rewrite Equation (8) as

$$S = {\sum }_{j = 1}^{4} {wj ( LEj )}^{2} \qquad ( 14 )$$

if dX=LE1, dY=LE2, dH=LE3 and dV=LE4. One can now include LR asymmetry in the merit function with a weight w5, to be chosen by the lithographer:

$$S = {\sum }_{j = 1}^{4} ( wj {\sum }_{x , j}^{} {( LEj )}^{2} ) + w5 {\sum }_{x , y}^{} {( LRasymmetry ( x , y ) )}^{2} . \qquad ( 15 )$$

With simulation software one can calculate the sensitivity coefficients for the lithographic error LRasymmetry(x,y) in analogy to equations (4)-(7), and proceed as described above.

Another example of a lithographic error which can be compensated for is the error known as Bossung tilt (also known as “iso-focal tilt”). It may occur when a phase shift mask (PSM) is used as patterning structure. Ideally, the phase shift between the regions of the mask is precisely 180 degrees. Any deviation from 180 degrees phase shift will cause a Bossung tilt (i.e. even at the best focus position, there is a gradient in the graph of exposed feature width against focus position (Bossung curve); therefore the process latitude is very poor, and in practice one may have to discard the mask).

However, it has been found that: (i) the phase error of a PSM; and (ii) spherical aberration (characterized by the Z9 Zernike parameter), have a similar impact on the Bossung curves, both leading to Bossung tilt. Therefore, a specific amount of spherical aberration can be introduced to cause Bossung tilt in one direction to cancel out a PSM phase error which causes Bossung tilt in the opposite direction. In this example, the merit function includes Bossung tilt, referred to hereafter as BT(x,y), which is a function of lens aberrations; in analogy with, for instance, equation (4) we may write
BT(x,y)=P1Z1(x,y)+P2Z2(x,y)+ . . . +P9Z9(x,y)+ . . . +P37Z37(x,y)+Q.θ (16)
In this example, the sensitivity coefficient P9 is relatively large with respect to the other sensitivity coefficients Pj, j=1,2, . . . 8,10, . . . , 37, θ is the PSM phase error, and Q is a sensitivity coefficient.

A compensator which is known primarily, to affect Z9 can now be used for counteracting the lithographic error Bossung tilt. If an optimal compromise between correcting for Bossung tilt, LR asymmetry, and the image shifts mentioned above is to be found, the merit function may be chosen to be

$$S = {\sum }_{j = 1}^{4} wj ( {\sum }_{x , y}^{} {( LEj )}^{2} ) + w5 {\sum }_{x , y}^{} {( LRasymmetry ( x , y ) )}^{2} + w6 {\sum }_{x , y}^{} {( BT ( x , y ) )}^{2} \qquad ( 17 )$$

A method of reducing errors according to another embodiment includes operations of lens characterization (e.g. as described above) and sensitivity coefficient calculation. In this method, the operation of calculating the sensitivity coefficients includes applying compensators in the form of sub-resolution assist features. At least one of a type, a size, and a placement of such assist features is selected to reduce sensitivity of the pattern to at least one lens nonideality.

The aberration-induced CD (critical dimension) variation of a pattern feature can be described by a linear superposition of measured aberration levels and calculated Zernike sensitivities:

$$dCD ( x , y ) = {\sum }_{j}^{} \frac{\partial CD}{\partial {Z}_{j}} \cdot {Z}_{j} ( x , y ) , \qquad ( 18 )$$

where dCD(x,y) denotes the CD change at a specific field position (x,y);

$$\frac{\partial CD}{\partial {Z}_{j}}$$

is a sensitivity coefficient expressing the CD sensitivity to the j-th Zernike polynomial and the Zernike coefficient; Zⱼ(x,y) is a lens property which represents the wavefront aberration at the field position (x,y). This property is also referred to as “CD uniformity” or “CDU.” Reduction of the CDU may be accomplished by (a) optimizing the sensitivity coefficients, which are functions of printing features and illumination conditions and resist process conditions, and/or (b) optimizing the aberration levels, which characterize the lens quality of the exposure tool and could be adjusted to a certain extent.

One typical method for optimizing the sensitivity coefficients is to change the illumination condition for a given feature. Since the CD sensitivities

$$\frac{\partial CD}{\partial {Z}_{j}}$$

are functions of printing feature type/size, illumination mode/setting and resist process conditions, a general approach for optimization of the sensitivity coefficients is to determine an illumination condition such that the CD variations are minimized for the specific feature. The optimal conditions including design pattern, illumination settings and resist process parameters are then fixed and applied for device manufacturing. A method according to an embodiment of the invention may be applied to further improve the LR asymmetry and/or CDU under the selected illumination and resist process conditions.

Without changing the initial illumination setting and resist process condition, a method according to one embodiment includes manipulating the design shape by application of additional and non-printable assist features (“sub-resolution assist features” or “SRAF”), such that the CD sensitivities

$$\frac{\partial CD}{\partial {Z}_{j}}$$

of the pattern feature are minimized. The SRAF may comprise chrome dots, or any other design objects of different sizes, shapes, and/or types, which can modulate the intensity and/or phase of the original pattern. In such a method, one or more aspects of the assist features are selected to reduce the aberration-induced image variation for a pattern and its sensitivity to aberrations. Therefore the CD variation as well as CDU may be improved.

One typical method for optimizing the aberration levels in expression (18) above is to adjust the lens aberration levels of exposure tools based on a set of reference structures. Generally, the aberration setup of an exposure tool is performed using a set of specific reference structures which are sensitive to a certain type of aberrations. However, a tool properly set up with these reference structures may not lead to an optimal CDU when a real customer design (e.g. one that is actually used in the manufacture of a device) is to be imaged. Thus, a more optimal CDU may be reached if the aberration setup were done based on the critical patterns to be imaged during use of the apparatus rather than the same reference structures defined by tool makers. In a method according to an embodiment, one or more SRAFs are applied to minimize CD sensitivity, using one or more patterns to be printed in the manufacture of a device rather than a set of reference structures. Moreover, as described herein, an aberration setup using such a pattern with SRAF can further improve CDU performance with available aberration manipulators of the exposure tools.

Sub-resolution assist features (AFs) may be applied to reduce the sensitivities of an arbitrary design with respect to correctable and/or non-correctable aberrations without changing the illumination conditions. Once the optimization of the aberration sensitivities is done, an aberration setup using the obtained pattern with sub-resolution AF can further improve CDU performance with available aberration manipulators of the exposure tools.

The assist features should be sufficiently small in at least one dimension so as not to appear in the developed pattern of the resist, though they may be detectable in the aerial image and may partially expose the photo- (energy sensitive) resist. The assist features are therefore generally smaller than the critical dimension of the mask pattern and the resolution limit of the lithographic apparatus with which the mask is to be used.

The pattern features may for example represent contact holes to be formed in a DRAM array. The pattern features and assist features may be transparent areas on a relatively opaque background or vice versa. In a reflective mask (e.g. a binary mask), the pattern features and assist features will have a different reflectivity than the background. In a phase shift mask, the isolated areas and assist features may introduce a different phase shift and/or a different attenuation than the background. The assist features need not have the same “tone” as the isolated areas.

The positions, shapes and sizes of the assist features may be determined by calculating aberrations in the wavefront that would be produced by the pattern without them and then determining sizes, positions, etc., for the assist features that reduce the predicted aberrations, especially 3 wave and 1 wave (comatic) aberrations.

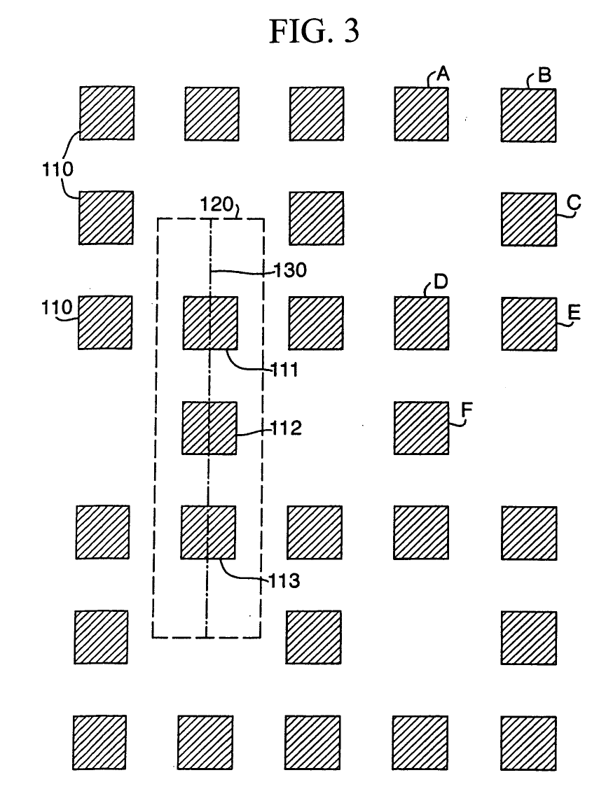

As an example of a pattern that may benefit from the application of assist features, FIG. 3 shows part of a conventional 6% attenuated phase shift mask pattern which may be used in a lithographic projection apparatus as described herein for forming contact holes (vias) in a dynamic random access memory (DRAM) device. The mask pattern has an array of transparent areas 110, which let through the exposure radiation to expose the resist in the areas where contact holes are to be formed, in a substantially opaque field. It will be seen that the transparent areas are arranged such that a group of three, referenced 111, 112, 113, repeats regularly. The contact holes are 0.2 microns square with the spacing between contacts 0.2 microns. A reference area 120 of 0.4×1.6 μm² is also shown.

The inventors have discovered that these contact holes do not image correctly, being misshapen and displaced from their nominal positions. Assist features may be added to the mask pattern to make the array of features more nearly symmetric. Suitable positions and dimensions for the assist features may be determined empirically by consideration of the Zernike coefficients representing wavefront aberrations in the image that will be produced from the pattern and postulated assist features.

The wavefront aberrations can be written as a series according to their angular form:

$$W ( r , θ ) = {\sum }_{m}^{} {R}_{m} ( r ) cos ( m θ ) + {R}_{m}^{′} ( r ) sin ( m θ ) \qquad ( 19 )$$

where r and θ are radial and angular co-ordinates, respectively, (r is normalized) and m is an index indicating the contribution of the mth aberration. R and R′ are functions of r.

The aberration can also be expressed in terms of the Zernike expansion as discussed above:
W=Zifᵢ(r,θ)+Zjfⱼ(r,θ)+Zkfₖ(r,θ)+ (20)
where each Z is the Zernike coefficient and each f is the corresponding Zernike polynomial. The functions f take the form of the product of a polynomial in r and sin or cos of mθ. For example, the comatic aberration (m=1) can be represented by a Zernike series in Z7, Z8, Z14, Z15, Z23, Z24, Z34, Z35 etc., and, for example, the function associated with the Z7 coefficient [f₇(r,θ) in the notation above] is:
(3r³−2r)cos(θ) (21)

The Zernike expansion for the lower-order aberrations is summarized in Table I below.

In particular, the inventors have determined that substantial improvements can be achieved by arranging assist features to manipulate the odd aberrations (odd m-numbers), especially the Z10 (3 wave) coefficient. Improvements can also be obtained by arranging assist features to reduce coma (1 wave) aberrations in the aerial image. The positions, shapes and sizes of assist features can be determined using known computational techniques, such as the program known as “Solid C”, a commercial software package supplied by the company Sigma-C GmbH in Germany, for simulating and modeling optical lithography. Other suitable software packages, such as one known as “Prolith”, may alternatively be used.

TABLE I

| Aberration | | Low-order Zernikes | | Higher orders |
|---|---|---|---|---|
| m | Name | Function | Term | Term |
| 0 | spherical | 6r⁴ − 6r² + 1 | Z9 | Z16, Z25, Z36, Z37 |
| 1 | X-coma | (3r³ − 2r) cos θ | Z7 | Z14, Z23, Z34 |
| 1 | Y-coma | (3r³ − 2r) sin θ | Z8 | Z15, Z24, Z35 |
| 2 | astigmatism | r² cos 2θ | Z5 | Z12, Z21, Z32 |
| 2 | 45° astigmatism | r² sin 2θ | Z6 | Z13, Z22, Z33 |
| 3 | X- three-point | r³ cos 3θ | Z10 | Z19, Z30 |
| 3 | Y- three-point | r³ sin 3θ | Z11 | Z20, Z31 |

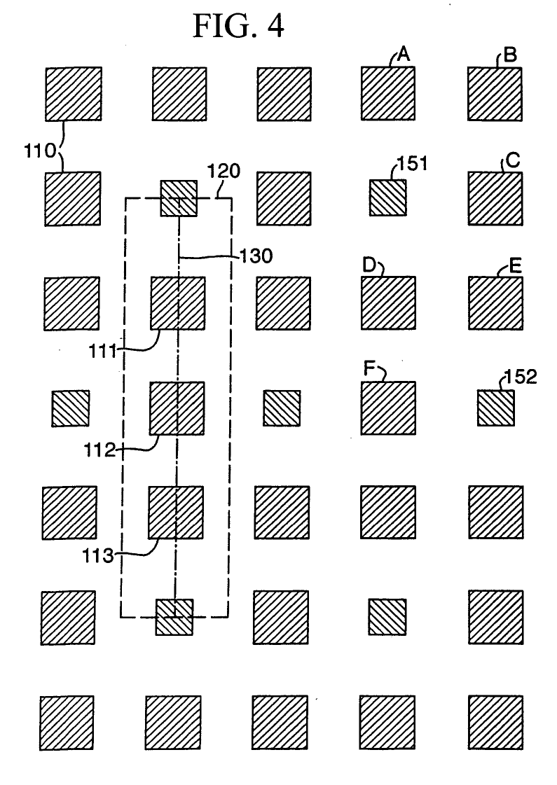

In the DRAM example, improvements may be achieved by regarding the six repeated transparent areas (see FIG. 4) as two pairs of triplets A, B, C and D, E, F with each member of the triplet occupying one of the four corners of a square (in this example) unit cell. According to the invention, assist features 151, 152 are placed at the fourth corners and comprise a transparent square of a size too small to be printed in the developed pattern. The squares can be 0.12 microns each side, for example. Note that the assist features may be visible in the aerial image and partly expose the resist but be washed out in development of the resist.

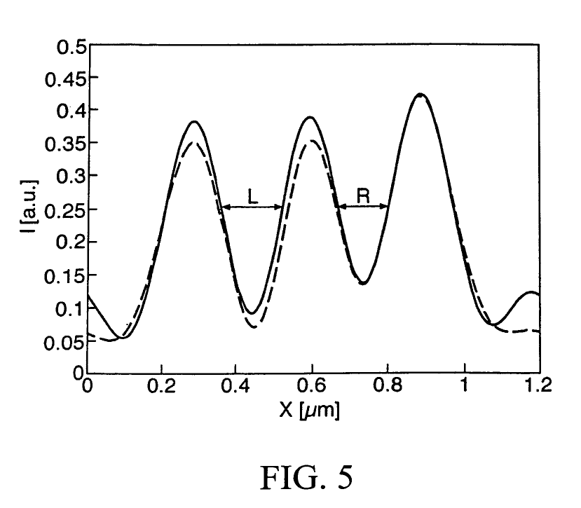

The efficacy of the use of such assist features may be seen in FIG. 5, which is a graph of intensity in the aerial images produced by the mask patterns of FIGS. 3 and 4 corresponding to the line 130. In FIG. 5, the solid line represents the intensity of the aerial images produced by the mask pattern with assist features (FIG. 4), and the dashed line represents the intensity of the aerial image produced by the conventional mask pattern (FIG. 3). The asymmetry of printing can be represented by the distances L and R shown in FIG. 5; these represent the distances between the peaks which will form the contact holes, measured at the resist threshold, chosen as 0.25 in the arbitrary units of the graph of FIG. 5. It can be seen that the distance L is reduced with the use of assist features so that the asymmetry represented by the difference (L−R) is also reduced.

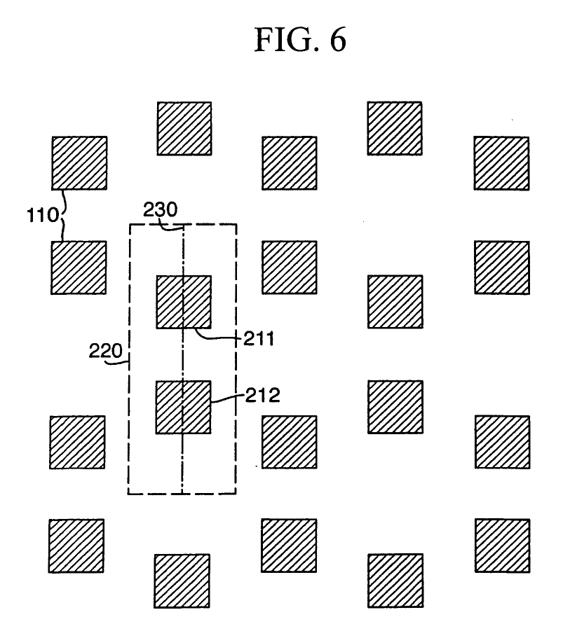

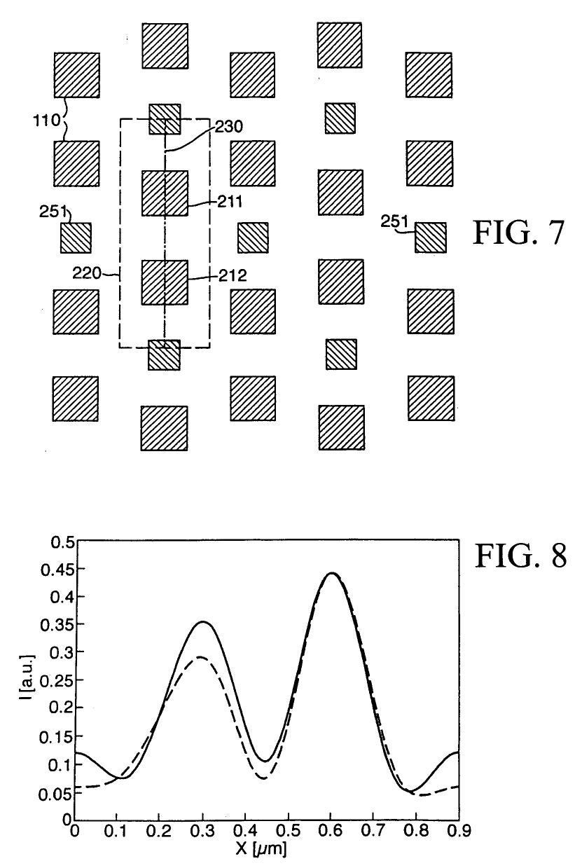

FIG. 6 shows an alternative arrangement of contact holes 110. In this arrangement a pair of contact holes 211, 212 repeats to form a honeycomb structure. The contact holes may be 0.2 microns square with a spacing between adjacent contacts of 0.2 microns. Also shown is a reference area 220 of 0.4×0.9 μm². According to this arrangement, the symmetry of this mask pattern is improved, as shown in FIG. 7, by adding an additional assist feature 251 at the center of each honeycomb cell. The assist features 251 may be square of side 0.12 microns, for example.

Another aspect of improvement can be seen in FIG. 8, which is a graph of intensities of the aerial images produced by the mask patterns of FIGS. 6 and 7 along the line 230. As with FIG. 5, the solid line represents the intensity of the image produced by the mask pattern according to the invention (FIG. 7) and the dashed line that of the conventional pattern (FIG. 6). It will clearly be seen that the aerial image produced by the pattern including assist features is less asymmetric.

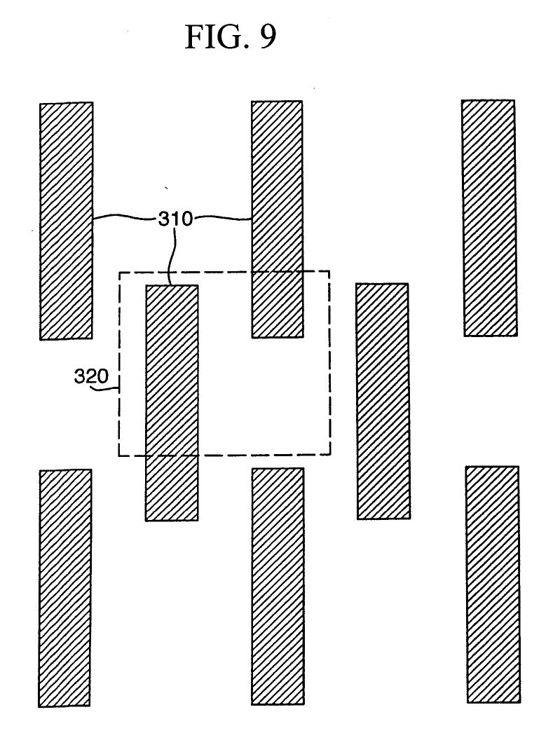

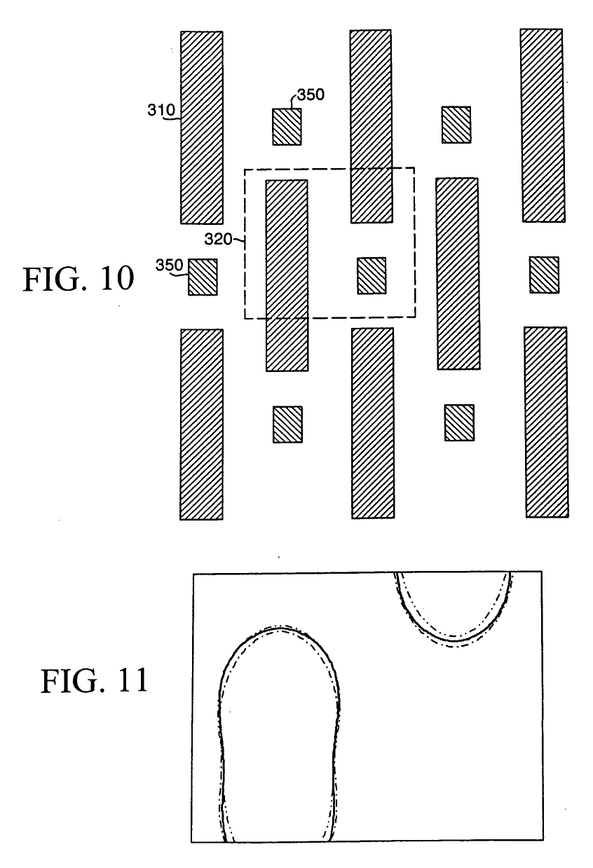

FIG. 9 shows a conventional “brick wall” pattern of rectangles arranged in a staggered array. The rectangles are 0.2×0.5 μm² with a spacing between adjacent rectangles of 0.2 microns. The reference area 320 is 0.6×0.6 μm². As shown in FIG. 10, according to another arrangement, assist features 350 are placed between the rectangles 310. The assist features may again be 0.12 microns on each side, for example.

FIG. 11 is a contour plot at a 0.25 (arbitrary units) intensity threshold of the aerial image produced by the unit cell 320. The finely-dashed line represents the image produced by the present invention (FIG. 10) while the single-chain line represents that produced by the conventional mask pattern (FIG. 9). The double-chain line represents an ideal aerial image of the mask pattern with no 3-wave aberration. It will clearly be seen that the image provided by the use of assist features is closer to the ideal.

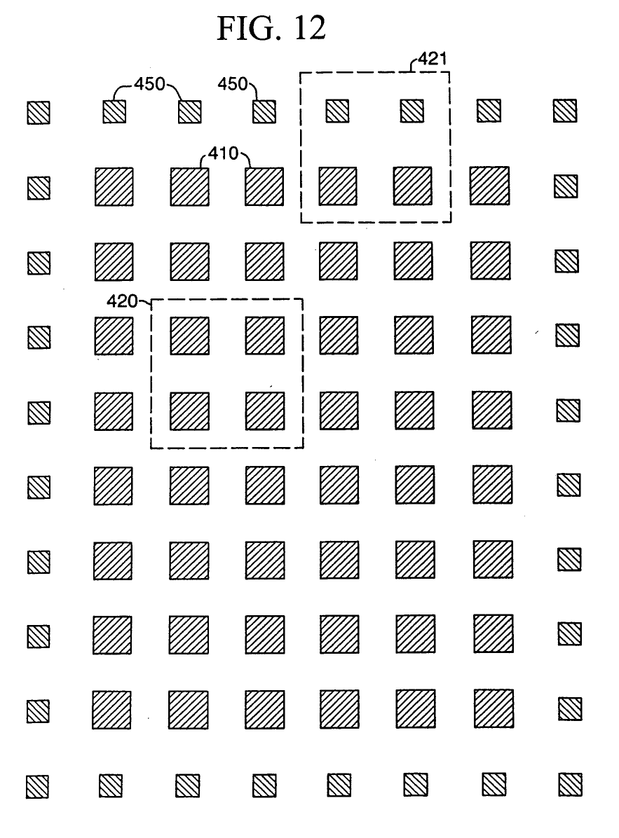

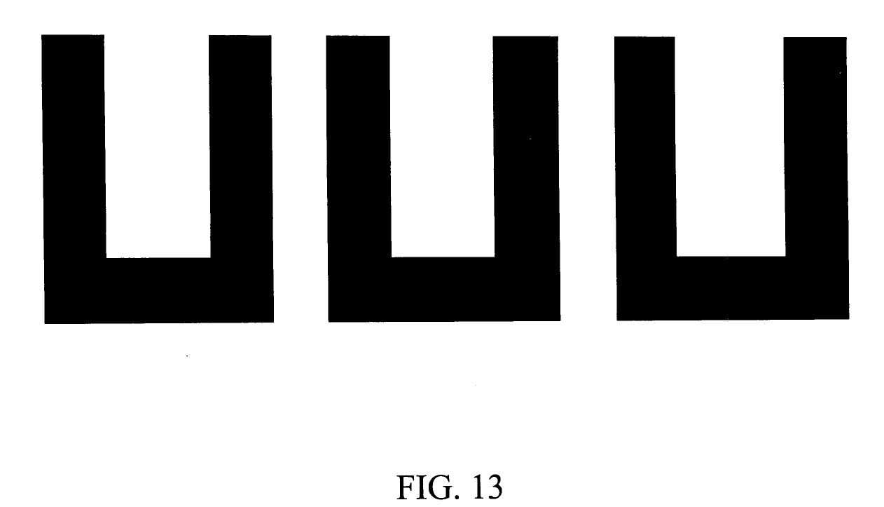

FIG. 12 shows a mask pattern according to another arrangement. This array comprises a regular rectangular array of features, e.g. contact holes 410. This array in itself is extremely regular and has a high degree of internal symmetry. However, by comparing the features within cell 420 with those within cell 421, it will be seen that there is a difference. The features 410 within cell 420 have neighbors on all sides whereas the features 410 in cell 421 have no neighbors outside them. Thus, assist features 450 may be provided outside the array of features 410 to provide pseudo-neighbors for the features at the edge of the regular array. Thus, cell 421 becomes more similar to cell 420. Accordingly, the assist features improve the translational symmetry of the array in that the viewpoint from a printing feature 410 at the edge of the array is made more similar to the viewpoint from a printing feature 410 in the middle of the array.

The sizes of the printing features 410 and assist features 450 may be similar to those described above and may be modified as desired for a specific application. Where the printing features forming the array are not square, the assist features may also be non-square but again sufficiently small so as to not print. Assist features around the outside of an array may of course be used in conjunction with assist features within the array itself. Further, where the image of a given assist feature is affected by features further away than its nearest neighbors, additional rows of assist features may be provided as necessary. In general, it may be preferable to provide assist features around all sides of the array of printing features, but the presence of other features near the array may make the provision of assist features around the entire periphery of the array unnecessary and/or impractical. While in FIG. 12 the assist features are shown spaced from the array by a distance equal to the array pitch, this distance may of course be varied to alter the effect of the assist features as desired.

In a method according to an embodiment, one or more assist features are placed into an area that is enclosed at least partially by a pattern feature. FIG. 13 shows a plurality of “U”-shaped pattern features, each of which partially encloses an area. In this example, the features are spaced with a certain pitch in the X direction. Such a pattern is relatively sensitive to 3-wave and 5-wave aberrations, which are unfortunately uncorrectable in the current exposure tools.

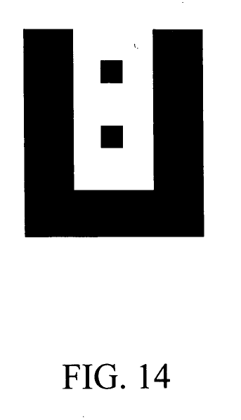

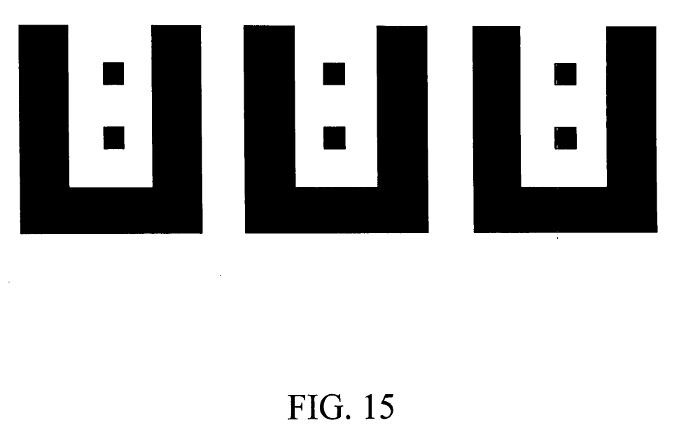

One method includes adding a sub-resolution assist feature inside the feature (see, e.g., FIG. 14) under the same illumination condition. In one example of applying one or more such features to a “U”-shaped pattern, a sensitivity reduction for LR asymmetry at the center of the vertical bars may be obtained as compared to the original “U”-shaped pattern without AF.

Concerning the selection of SRAF size and placement, we can use the following algorithm:

for AF type = {BIM, PSM,...}
for AF size s = s1 to s2,
for AF separation from designated feature point y = y1 to y2,
M (s, y) = function(sens ⱼ (s, y))
end
end
end

where BIM indicates a binary mask, M(s,y) is a merit function which can take a form as above (e.g. expression (18)) or can be chosen depending on applications, and

$${sens}_{j} ( s , y ) = \frac{\partial ( L - R )}{\partial {Z}_{j}}$$

is the sensitivity of LR asymmetry with respect to the jth Zernike polynomial and varies as a function of AF size and location. The designated feature point may be chosen for convenience or according to a region of interest. In the example of FIG. 14, the designated feature point may be the intercept point of the vertical axis of symmetry on the inner perimeter of the “U”-shaped feature, and the separations y may be different distances from the intercept point along that axis (in this example, a square AF is placed along the vertical axis of symmetry of the “U” pattern). In such manner, an iterative algorithm may be applied to find out an optimal AF type, size and placement such that the overall Zernike sensitivities are minimized.

In another embodiment, multiple SRAFs are applied inside the pattern features, where the size and shape of the AFs may be different. For example, the application of two AFs inside a “U”-shaped pattern along its vertical axis of symmetry may reduce not only the mean sensitivity of LR asymmetry but also the variation (range) of LR asymmetry along the vertical bars. Different types of AF may also be used, with different sizes placed at different locations inside a feature. FIG. 15 illustrates assist features being applied at a same location within the “U”-shaped pattern. However, the assist features may be applied at different locations within similar pattern features.

Assist features may be applied to largely reduce the sensitivities to higher order aberrations, while the sensitivities to lower order may be increased slightly. Fortunately modern scanners are provided with some control knobs on lower order aberrations. So based on the aberration sensitivities of, e.g., the obtained “U”-shaped pattern with SR AF, the aberration control knobs of the exposure tool can be used to compensate the contribution of the uncorrectable aberrations to CDU.

A method according to one embodiment includes applying an algorithm to reduce the sensitivities to the uncorrectable aberrations in optimizing the placement and size of the assist feature. Then based on the aberration sensitivities of the obtained pattern (e.g. one or more of a pattern that at least partially encloses an area, such as a “U”-shaped pattern) with sub-resolution AF, the aberration control knobs of the exposure tool can be used to compensate the contribution of the uncorrectable aberrations to CDU.

A method according to one embodiment includes obtaining a simultaneous optimization of the Zernike sensitivities using sub-resolution AF and the aberration levels based on customer specific design without changing the illumination condition and without any impact on other device patterns.

Embodiments of the invention include methods of manipulating the design shape with the application of SRAF to minimize the aberration sensitivity of a pattern feature without changing the original tool setting and resist process condition. Moreover, the combination with the “customized aberration setup” using the obtained customer pattern with SRAF can further improve the CDU performance with available aberration manipulators of the exposure tools.

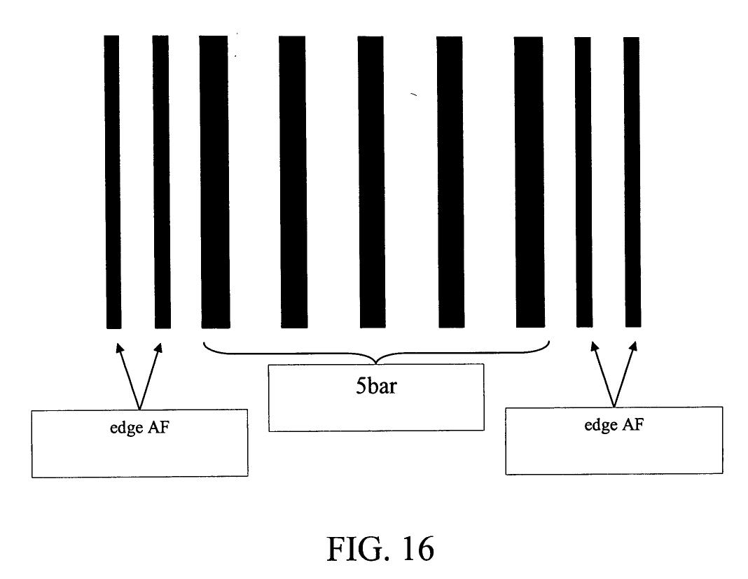

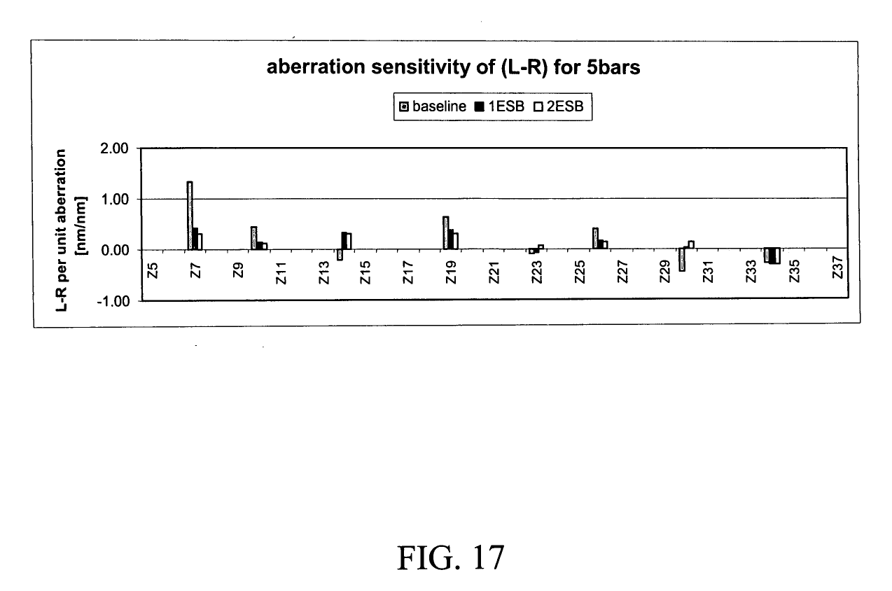

Other pattern features to which assist features may be applied to reduce sensitivities to system nonidealities (e.g. Zernike sensitivities) include a one-dimensional non-periodical structure such as N-bar structure. The N-bar structure (such as 5 bar, as shown in FIG. 16 with edge AF applied according to an embodiment) is in general sensitive to odd aberrations. The graph in FIG. 17 shows an effect of the application of one or two nonprintable edge AF (denoted ESB) outside the N-bar structure in reducing the LR asymmetry of the structure.

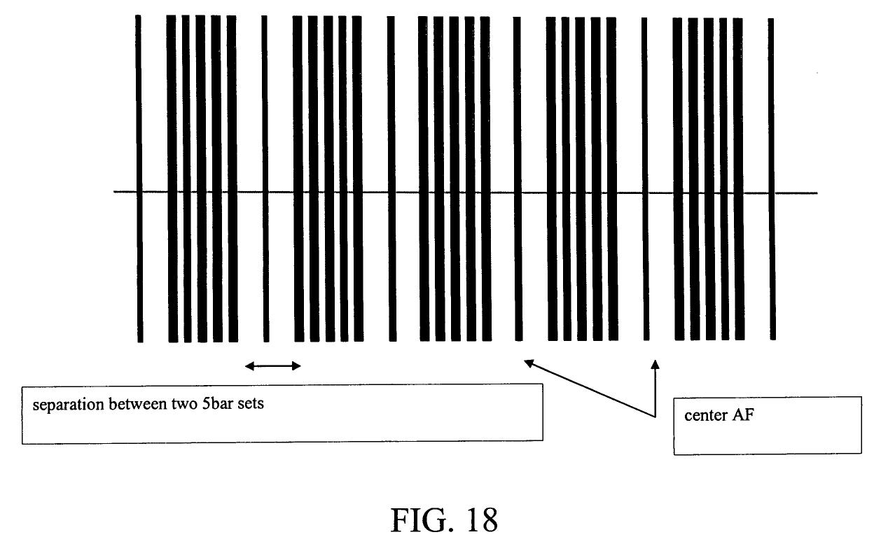

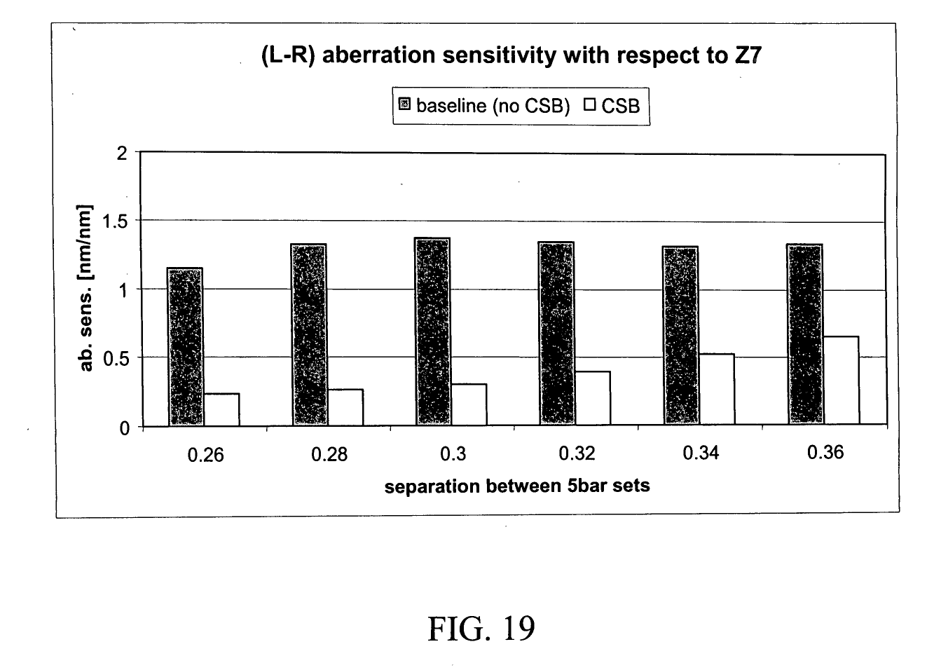

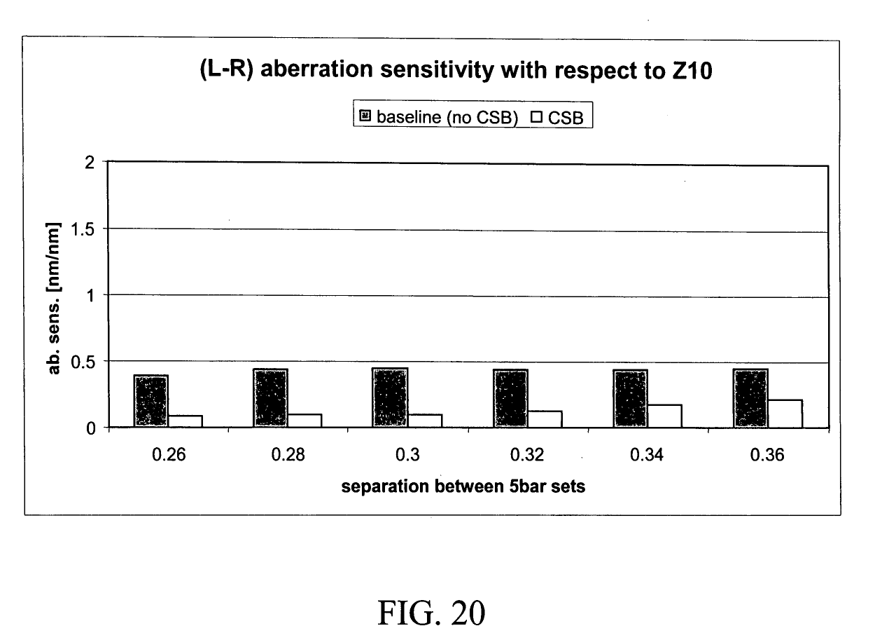

Further more, the application of SRAF can be extended to a series of N-bar structure sets. As illustrated in FIG. 18, a nonprintable center AF (denoted CSB) may be inserted between sets of 5 bar structure, which reduces significantly the sensitivity to odd aberrations (in other embodiments, more than one CSB may be used between two sets of N-bar structure). The graphs of FIGS. 19 and 20 show the (L−R) sensitivity improvement to 1 wave and to 3 wave aberrations, respectively, where the extent of improvement depends on the separation between two sets of 5 bar.

While we have described above specific embodiments of the invention, it will be appreciated that the invention may be practiced otherwise than as described. For example, the invention may take the form of a computer program containing one or more sequences of machine-readable instructions describing a method as disclosed above, or a data storage medium (e.g. semiconductor memory, magnetic or optical disk) having such a computer program stored therein. Thus the description is not intended to limit the invention. It is explicitly noted that principles as disclosed herein can also be applied to a mask pattern having an asymmetric array or group of features. It is noted that embodiments of the invention may also be applied where the array comprises only part of the mask pattern, for example in the manufacture of system-on-chip devices combining memory and logic or processors on a single device.

1. A device manufacturing method comprising:
selecting an exposure condition, said exposure condition including at least one of the group consisting of an illumination condition and a resist process condition;
determining a sensitivity of a pattern to a nonideality of a lithographic apparatus, wherein the sensitivity is based on the selected exposure condition;
adding a plurality of non-printing assist features to the pattern to obtain a modified pattern, said adding including selecting at least one of the group consisting of a type, a size, and a location of each of the plurality of non-printing assist features to reduce the sensitivity; and
projecting a beam of radiation patterned according to the modified pattern.

2. The device manufacturing method according to claim 1, wherein the nonideality of a lithographic apparatus includes an aberration of a lens arranged to project the beam of radiation.

3. The device manufacturing method according to claim 1, wherein the pattern includes a pattern feature that at least partially encloses an area, and
wherein an assist feature of the plurality of non-printing assist features is arranged within the area.

4. The device manufacturing method according to claim 1, wherein the pattern includes a series of elongated bars arranged to be substantially parallel to one another, and
wherein an assist feature of the plurality of non-printing assist features is arranged at an edge of the series.

5. The device manufacturing method according to claim 1, wherein the pattern includes a plurality of series of elongated bars, the bars in each series arranged to be substantially parallel to one another and to the bars in the others of the plurality of series, and
wherein an assist feature of the plurality of non-printing assist features is arranged between adjacent ones of the plurality of series.

6. The device manufacturing method according to claim 1, wherein said selecting an exposure condition comprises selecting an illumination condition, and
wherein said projecting a beam-is performed according to the illumination condition.

7. The device manufacturing method according to claim 1, said method comprising, prior to said projecting, correcting an aberration induced by the modified pattern.

8. A method of making a mask, said method comprising:
defining a plurality of pattern features that contrast with a background and represent features to be printed in manufacture of a device, each of said pattern features being configured to at least partially enclose an area; and
defining a plurality of non-printing assist features that contrast with the background and are smaller than said pattern features,
wherein said defining a plurality of assist features comprises selecting at least one of the group consisting of a type, a size, and a location of each of the plurality of non-printing assist features to reduce a sensitivity of the pattern to a system nonideality.

9. The method of making a mask according to claim 8, wherein the nonideality of a lithographic apparatus includes an aberration of a lens arranged to project the beam of radiation.

10. The method of making a mask according to claim 8, wherein the pattern includes a pattern feature that at least partially encloses an area, and
wherein an assist feature of the plurality of non-printing assist features is arranged within the area.

11. The method of making a mask according to claim 8, wherein the pattern includes a series of elongated bars arranged to be substantially parallel to one another, and
wherein an assist feature of the plurality of non-printing assist features is arranged at an edge of the series.

12. The method of making a mask according to claim 8, wherein the pattern includes a plurality of series of elongated bars, the bars in each series arranged to be substantially parallel to one another and to the bars in the others of the plurality of series, and
wherein an assist feature of the plurality of non-printing assist features is arranged between adjacent ones of the plurality of series.

13. A mask comprising:
a plurality of pattern features that contrast with a background and represent features to be printed in manufacture of a device, each of said pattern features being configured to at least partially enclose an area; and
a plurality of non-printing assist features that contrast with the background and are smaller than said pattern features,
wherein said plurality of assist features is arranged to reduce a sensitivity of the pattern to a system nonideality under a predetermined illumination condition.

14. The mask according to claim 13, wherein the pattern includes a pattern feature that at least partially encloses an area, and
wherein an assist feature of the plurality of non-printing assist features is arranged within the area.

15. The mask according to claim 13, wherein the pattern includes a series of elongated bars arranged to be substantially parallel to one another, and
wherein an assist feature of the plurality of non-printing assist features is arranged at an edge of the series.

16. The mask according to claim 13, wherein the pattern includes a plurality of series of elongated bars, the bars in each series arranged to be substantially parallel to one another and to the bars in the others of the plurality of series, and
wherein an assist feature of the plurality of non-printing assist features is arranged between adjacent ones of the plurality of series.

17. A method of reducing aberration sensitivity for selected pattern features on a mask having a design shape that includes a plurality of pattern features, said method comprising:
maintaining at least one of a tool setting, a resist process condition, and an initial illumination setting;
changing the design shape by locating one or more non-printing assist features proximate to the selected pattern features, wherein the one or more non-printing assist features are located to minimize an aberration sensitivity of the selected pattern features; and
enabling adjustment of aberration manipulators on an exposure tool.

18. The method of claim 17, wherein the one or more non-printing assist features are located to reduce a sensitivity of the pattern features to a system nonideality.

19. The method of claim 17, wherein the one or more non-printing assist features are selected based on at least one of a sizes and a shape.

20. The method of claim 17, wherein the one or more non-printing assist features are located to modulate at least one of an intensity and phase of the pattern features.

21. The method of claim 17, wherein the one or more non-printing assist features are smaller than a resolution limit of a lithographic device that exposes the mask.
